(19) United States
(12) Patent Application Publication
(10) Pub. No.: US 2026/0352380 A1
(43) Pub. Date: Nov. 5, 2026

(54) SYSTEMS AND METHODS FOR HARQ FEEDBACK ENHANCEMENT

(71) Applicant: InterDigital Patent Holdings, Inc., Wilmington, DE (US)

(72) Inventors: Mohamed Amine Arfaoui, Montreal (CA); Philip Pietraski, Jericho, NY (US); Guodong Zhang, Woodbury, NY (US); Asil Koc, Verdun (CA); John Kaewell, Jamison, PA (US); Daniel Steinbach, Commack, NY (US)

(73) Assignee: InterDigital Patent Holdings, Inc., Wilmington, DE (US)

(21) Appl. No.: 19/197,646

(22) Filed: May 2, 2025

(51) Int. Cl. H04L 1/1812; H03M 13/09; H03M 13/39; H04L 1/00; H04L 5/00

(52) U.S. Cl. CPC H04L 1/1812; H03M 13/09; H03M 13/3927; H04L 1/0003; H04L 5/0053

(57) ABSTRACT

A wireless transmit/receive unit (WTRU) may receive configuration information, for example from a network (NW). The configuration information may include an indication of a hybrid automatic request (HARQ) feedback report type and/or an HARQ feedback report format. The WTRU may determine one or more one decoding parameter. The one or more decoding parameter may include one or more of a soft combining feedback message, a decoding feedback message, and/or a cyclic redundancy check (CRC) message. The WTRU may determine the HARQ feedback report type, the HARQ feedback report format, and/or an HARQ feedback report, for example based on the configuration information and/or the one or more decoding parameter. The WTRU may send the HARQ feedback report, for example to the network. The WTRU may send the HARQ feedback report type and/or the HARQ feedback report format with the HARQ feedback report.

### BACKGROUND

Artificial intelligence (AI) may include behavior exhibited by machines that, for example may mimic cognitive functions to sense, reason, adapt, and/or act. An AI component may include the realization of behaviors and/or conformance to requirements by learning based on data, for example without explicit configuration of sequence of steps of actions. An AI component may enable learning complex behaviors. Complex behaviors may be difficult to specify and/or implement when using legacy methods.

Machine learning (ML) may include algorithms (e.g., types of algorithms) that solve a problem based on learning through experience (e.g., data), for example without being explicitly programmed (e.g., configuring a set of rules). ML may be a subset of AI. Different ML paradigms may be envisioned, for example based on the nature of data or feedback available to the learning algorithm. A supervised learning approach may involve learning a function that maps input to an output based on labeled training example. A (e.g., each) training example may include a pair. The pair may include an input and a corresponding output. An unsupervised learning approach may involve detecting patterns in the data with no pre-existing labels. A reinforcement learning approach may involve performing a sequence of actions in an environment, for example to maximize the cumulative reward. ML algorithms may be applied using a combination and/or interpolation of the approaches herein. For example, a semi-supervised learning approach may use a combination of a small amount of labeled data with a large amount of unlabeled data during training. Semi-supervised learning may fall between unsupervised learning (e.g., with no labeled training data) and supervised learning (e.g., with only labeled training data).

Deep learning may include a class of ML algorithms that may employ artificial neural networks, for example deep neural networks (DNNs). DNNs may be (e.g., loosely) inspired by biological systems. The DNNs may be a special class of ML models that may be inspired by the human brain. The input may be linearly transformed and/or pass through non-linear activation function multiple times. DNNs may include multiple layers. A (e.g., each) layer may include a linear transformation and/or a given non-linear activation function. The DNNs may be trained using the training data, for example via back-propagation algorithm. DNNs may be utilized in a variety of domains including, for example speech, vision, natural language, and/or wireless communication, etc., and/or for (e.g., various) ML settings, for example supervised, un-supervised, semi-supervised, and/or etc.

### SUMMARY

A wireless transmit/receive unit (WTRU) may receive configuration information, for example from a network (NW). The configuration information may include an indication of a hybrid automatic request (HARQ) feedback report type and/or an HARQ feedback report format. The WTRU may receive, from the network, a downlink (DL) scheduling message and/or a DL transmission associated with the DL scheduling message (e.g., scheduled by the DL scheduling message). The WTRU may determine one or more decoding parameters, for example based on the DL transmission. The one or more decoding parameters may include one or more of a soft combining feedback message, a decoding feedback message, a cyclic redundancy check (CRC) feedback message, a (e.g., requested) MCS, a new data indicator (NDI), a code block group transmission information (CBGTI), and/or a code block group flushing out information (CBGFI). The WTRU may determine the HARQ feedback report type, the HARQ feedback report format, and/or the HARQ feedback report, for example based on the configuration information and/or the one or more decoding parameters. The WTRU may send the HARQ feedback report, for example to the network.

The WTRU may generate the HARQ feedback report based on one or more of the decoding parameters, the DL transmission, and/or the DL scheduling message. The HARQ feedback report may be associated with the HARQ feedback report type and/or the HARQ feedback report format. The HARQ feedback report may include an indication of at least one of a log-likelihood ratio (LLR) of coded bits associated with the soft combining feedback message, a decoding complexity associated with the downlink transmission, and/or cyclic redundancy check (CRC) bits associated with the CRC feedback message. The HARQ feedback report format may include an explicit indication or a latent representation for the HARQ feedback report.

The downlink scheduling message may include one or more of a modulation and coding scheme (MCS), a data allocation associated with one or more transport blocks (TBs), a HARQ process identifier (ID) associated with the one or more TBs, code block group (CBG) transmission information (CBGTI), and/or CBG flushing out information (CBGFI) associated with the CBG. The soft combining feedback message may include an indication of one or more of a log likelihood ratios (LLR) and/or a signal to interference plus noise ratio (SINR). The decoding feedback message may include an indication of forward error correction (FEC). The CRC feedback message may include an indication of at least one of a cyclic redundancy check (CRC), an acknowledgment (ACK), and/or a non-acknowledgment (NACK).

The WTRU may receive a request to transmit HARQ feedback capabilities to the network. The WTRU may transmit the HARQ feedback capabilities to the network, for example in response to the request. The HARQ feedback capabilities may include an indication that the WTRU supports artificial intelligence/machine learning (AI/ML) HARQ feedback. The WTRU may receive an AI/ML model for HARQ feedback.

The HARQ feedback report comprises an indication of one or more of log-likelihood ratio (LLR) of the coded bits from the soft combining feedback message, a decoding complexity associated with the downlink transmission from the decoding feedback message, and/or the reconstructed data and CRC bits from the CRC feedback message. The soft combining feedback message may include information about the soft combining operation at the WTRU (e.g., statistics of log likelihood ratios (LLRs) after soft combining, resulting signal to interference plus noise ratio (SINR) after soft combining, etc.). The decoding feedback message may include information and/or statistics about the forward error correction (FEC) decoding process at the WTRU (e.g., the number of iterations that the FEC decoder used to decode the resulting LLRs). The CRC feedback message may include information about the CRC validation process at the WTRU (e.g. ACK/NACK bits, total set of CRC bits after CRC validation). The WTRU may determine the HARQ feedback report based on one or more of the soft combining feedback message, the decoding feedback message, the cyclic redundancy check (CRC) feedback message, the requested MCS, the NDI, the CBGTI, and/or the CBGFI. The WTRU may send the HARQ feedback report, the HARQ feedback report type, and/or the HARQ feedback report format, for example to the network.

The WTRU may determine the HARQ feedback report based on one or more function parameter of an artificial intelligence/machine learning (AI/ML)-based function. The one or more function parameter may be based on the one or more decoding parameters, a modulation and coding scheme (MCS), a new data indicator (NDI), a code block group transmission information (CBGTI), and/or a code block group flushing out information (CBGFI). The WTRU may determine the HARQ feedback report based on an artificial intelligence/machine learning (AI/ML) compression rate.

### BRIEF DESCRIPTION OF THE DRAWINGS

FIG. 1A is a system diagram illustrating an example communications system in which one or more disclosed embodiments may be implemented.

FIG. 1B is a system diagram illustrating an example wireless transmit/receive unit (WTRU) that may be used within the communications system illustrated in FIG. 1A according to an embodiment.

FIG. 1C is a system diagram illustrating an example radio access network (RAN) and an example core network (CN) that may be used within the communications system illustrated in FIG. 1A according to an embodiment.

FIG. 1D is a system diagram illustrating a further example RAN and a further example CN that may be used within the communications system illustrated in FIG. 1A according to an embodiment.

FIG. 2 is an example of an automatic repeat request (ARQ) protocol.

FIG. 3 is an example of a hybrid automatic repeat request (HARQ) protocol.

FIG. 4 is an example of enhanced HARQ feedback.

FIG. 5 is an example procedure for enhanced HARQ feedback.

FIG. 6 is an example AI/ML model of a HARQ generation function at a WTRU.

FIG. 7 is an example AI/ML model of a HARQ processing function at a network.

### DETAILED DESCRIPTION

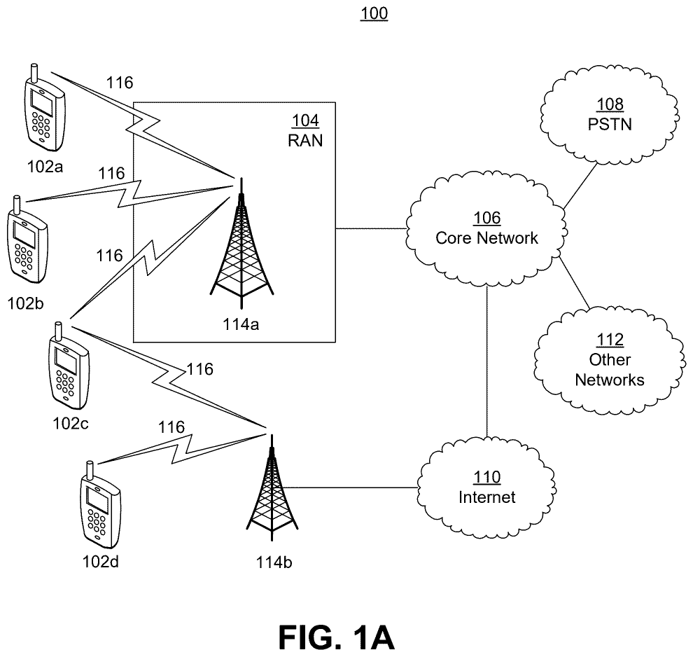

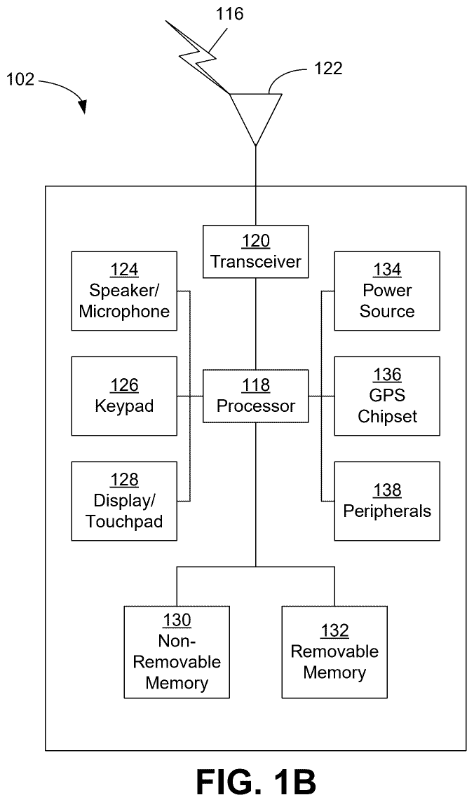

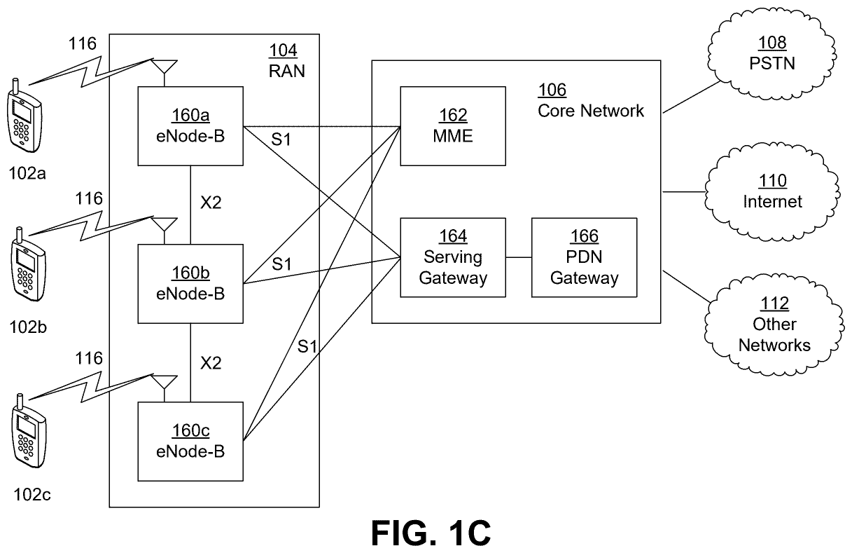

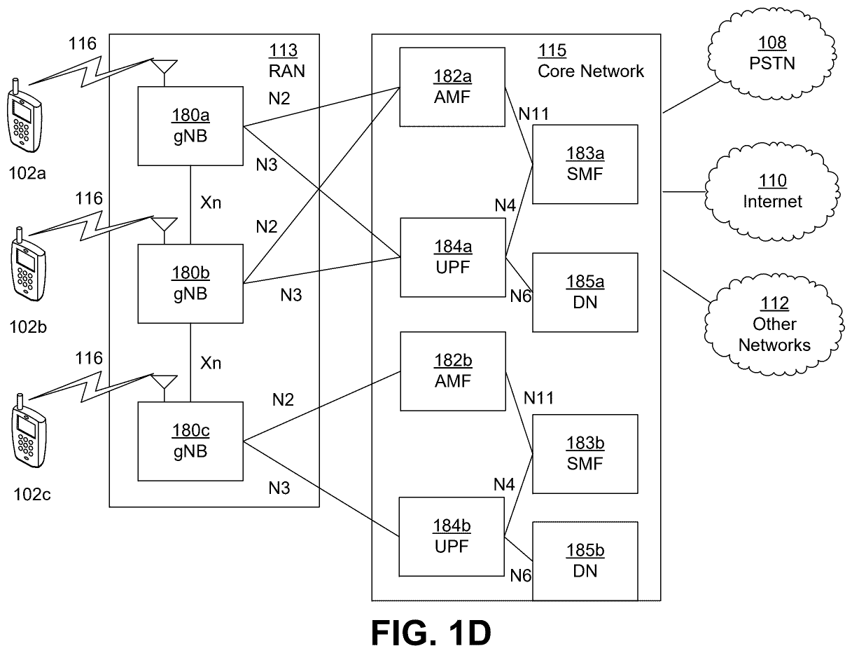

FIG. 1A is a diagram illustrating an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), zero-tail unique-word DFT-Spread OFDM (ZT UW DTS-s OFDM), unique word OFDM (UW-OFDM), resource block-filtered OFDM, filter bank multicarrier (FBMC), and the like.

As shown in FIG. 1A, the communications system 100 may include wireless transmit/receive units (WTRUs) 102a, 102b, 102c, 102d, a RAN 104/113, a CN 106/115, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d, any of which may be referred to as a “station” and/or a “STA”, may be configured to transmit and/or receive wireless signals and may include a user equipment (UE), a mobile station, a fixed or mobile subscriber unit, a subscription-based unit, a pager, a cellular telephone, a personal digital assistant (PDA), a smartphone, a laptop, a netbook, a personal computer, a wireless sensor, a hotspot or Mi-Fi device, an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. Any of the WTRUs 102a, 102b, 102c and 102d may be interchangeably referred to as a WTRU. Further, any description herein that is described with reference to a UE may be equally applicable to a WTRU (or vice versa). For example, a WTRU may be configured to perform any of the processes or procedures described herein as being performed by a UE (or vice versa).

The communications systems 100 may also include a base station 114a and/or a base station 114b. Each of the base stations 114a, 114b may be any type of device configured to wirelessly interface with at least one of the WTRUs 102a, 102b, 102c, 102d to facilitate access to one or more communication networks, such as the CN 106/115, the Internet 110, and/or the other networks 112. By way of example, the base stations 114a, 114b may be a base transceiver station (BTS), a Node-B, an eNode B, a Home Node B, a Home eNode B, a gNB, a NR NodeB, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104/113, which may also include other base stations and/or network elements (not shown), such as a base station controller (BSC), a radio network controller (RNC), relay nodes, etc. The base station 114a and/or the base station 114b may be configured to transmit and/or receive wireless signals on one or more carrier frequencies, which may be referred to as a cell (not shown). These frequencies may be in licensed spectrum, unlicensed spectrum, or a combination of licensed and unlicensed spectrum. A cell may provide coverage for a wireless service to a specific geographical area that may be relatively fixed or that may change over time. The cell may further be divided into cell sectors. For example, the cell associated with the base station 114a may be divided into three sectors. Thus, in one embodiment, the base station 114a may include three transceivers, i.e., one for each sector of the cell. In an embodiment, the base station 114a may employ multiple-input multiple output (MIMO) technology and may utilize multiple transceivers for each sector of the cell. For example, beamforming may be used to transmit and/or receive signals in desired spatial directions.

The base stations 114a, 114b may communicate with one or more of the WTRUs 102a, 102b, 102c, 102d over an air interface 116, which may be any suitable wireless communication link (e.g., radio frequency (RF), microwave, centimeter wave, micrometer wave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104/113 and the WTRUs 102a, 102b, 102c may implement a radio technology such as Universal Mobile Telecommunications System (UMTS) Terrestrial Radio Access (UTRA), which may establish the air interface 115/116/117 using wideband CDMA (WCDMA). WCDMA may include communication protocols such as High-Speed Packet Access (HSPA) and/or Evolved HSPA (HSPA+). HSPA may include High-Speed Downlink (DL) Packet Access (HSDPA) and/or High-Speed UL Packet Access (HSUPA).

In an embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A) and/or LTE-Advanced Pro (LTE-A Pro).

In an embodiment, the base station 114a and the WTRUs 102a, 102b, 102c may implement a radio technology such as NR Radio Access, which may establish the air interface 116 using New Radio (NR).

In an embodiment, the base station 114a and the WTRUs 102a, 102b, 102c may implement multiple radio access technologies. For example, the base station 114a and the WTRUs 102a, 102b, 102c may implement LTE radio access and NR radio access together, for instance using dual connectivity (DC) principles. Thus, the air interface utilized by WTRUs 102a, 102b, 102c may be characterized by multiple types of radio access technologies and/or transmissions sent to/from multiple types of base stations (e.g., a eNB and a gNB).

In other embodiments, the base station 114a and the WTRUs 102a, 102b, 102c may implement radio technologies such as IEEE 802.11 (i.e., Wireless Fidelity (WiFi), IEEE 802.16 (i.e., Worldwide Interoperability for Microwave Access (WiMAX)), CDMA2000, CDMA2000 1X, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, an industrial facility, an air corridor (e.g., for use by drones), a roadway, and the like. In one embodiment, the base station 114b and the WTRUs 102c, 102d may implement a radio technology such as IEEE 802.11 to establish a wireless local area network (WLAN). In an embodiment, the base station 114 b and the WTRUs 102 c, 102 d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, LTE-A Pro, NR etc.) to establish a picocell or femtocell. As shown in FIG. 1A, the base station 114b may have a direct connection to the Internet 110. Thus, the base station 114b may not be required to access the Internet 110 via the CN 106/115.

The RAN 104/113 may be in communication with the CN 106/115, which may be any type of network configured to provide voice, data, applications, and/or voice over internet protocol (VoIP) services to one or more of the WTRUs 102a, 102b, 102c, 102d. The data may have varying quality of service (QoS) requirements, such as differing throughput requirements, latency requirements, error tolerance requirements, reliability requirements, data throughput requirements, mobility requirements, and the like. The CN 106/115 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104/113 and/or the CN 106/115 may be in direct or indirect communication with other RANs that employ the same RAT as the RAN 104/113 or a different RAT. For example, in addition to being connected to the RAN 104/113, which may be utilizing a NR radio technology, the CN 106/115 may also be in communication with another RAN (not shown) employing a GSM, UMTS, CDMA 2000, WiMAX, E-UTRA, or WiFi radio technology.

The CN 106/115 may also serve as a gateway for the WTRUs 102a, 102b, 102c, 102d to access the PSTN 108, the Internet 110, and/or the other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and/or the internet protocol (IP) in the TCP/IP internet protocol suite. The networks 112 may include wired and/or wireless communications networks owned and/or operated by other service providers. For example, the networks 112 may include another CN connected to one or more RANs, which may employ the same RAT as the RAN 104/113 or a different RAT.

Some or all of the WTRUs 102a, 102b, 102c, 102d in the communications system 100 may include multi-mode capabilities (e.g., the WTRUs 102a, 102b, 102c, 102d may include multiple transceivers for communicating with different wireless networks over different wireless links). For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram illustrating an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and/or other peripherals 138, among others. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, a base station (e.g., the base station 114a) over the air interface 116. For example, in one embodiment, the transmit/receive element 122 may be an antenna configured to transmit and/or receive RF signals. In an embodiment, the transmit/receive element 122 may be an emitter/detector configured to transmit and/or receive IR, UV, or visible light signals, for example. In yet another embodiment, the transmit/receive element 122 may be configured to transmit and/or receive both RF and light signals. It will be appreciated that the transmit/receive element 122 may be configured to transmit and/or receive any combination of wireless signals.

Although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as NR and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs and/or video), a universal serial bus (USB) port, a vibration device, a television transceiver, a hands free headset, a Bluetooth® module, a frequency modulated (FM) radio unit, a digital music player, a media player, a video game player module, an Internet browser, a Virtual Reality and/or Augmented Reality (VR/AR) device, an activity tracker, and the like. The peripherals 138 may include one or more sensors, the sensors may be one or more of a gyroscope, an accelerometer, a hall effect sensor, a magnetometer, an orientation sensor, a proximity sensor, a temperature sensor, a time sensor; a geolocation sensor; an altimeter, a light sensor, a touch sensor, a magnetometer, a barometer, a gesture sensor, a biometric sensor, and/or a humidity sensor.

The WTRU 102 may include a full duplex radio for which transmission and reception of some or all of the signals (e.g., associated with particular subframes for both the UL (e.g., for transmission) and downlink (e.g., for reception) may be concurrent and/or simultaneous. The full duplex radio may include an interference management unit 139 to reduce and or substantially eliminate self-interference via either hardware (e.g., a choke) or signal processing via a processor (e.g., a separate processor (not shown) or via processor 118). In an embodiment, the WRTU 102 may include a half-duplex radio for which transmission and reception of some or all of the signals (e.g., associated with particular subframes for either the UL (e.g., for transmission) or the downlink (e.g., for reception)).

FIG. 1C is a system diagram illustrating the RAN 104 and the CN 106 according to an embodiment. As noted above, the RAN 104 may employ an E-UTRA radio technology to communicate with the WTRUs 102a, 102b, 102c over the air interface 116. The RAN 104 may also be in communication with the CN 106.

The RAN 104 may include eNode-Bs 160a, 160b, 160c, though it will be appreciated that the RAN 104 may include any number of eNode-Bs while remaining consistent with an embodiment. The eNode-Bs 160a, 160b, 160c may each include one or more transceivers for communicating with the WTRUs 102a, 102b, 102c over the air interface 116. In one embodiment, the eNode-Bs 160a, 160b, 160c may implement MIMO technology. Thus, the eNode-B 160a, for example, may use multiple antennas to transmit wireless signals to, and/or receive wireless signals from, the WTRU 102a.

Each of the eNode-Bs 160a, 160b, 160c may be associated with a particular cell (not shown) and may be configured to handle radio resource management decisions, handover decisions, scheduling of users in the UL and/or DL, and the like. As shown in FIG. 1C, the eNode-Bs 160a, 160b, 160c may communicate with one another over an X2 interface.

The CN 106 shown in FIG. 1C may include a mobility management entity (MME) 162, a serving gateway (SGW) 164, and a packet data network (PDN) gateway (or PGW) 166. While each of the foregoing elements are depicted as part of the CN 106, it will be appreciated that any of these elements may be owned and/or operated by an entity other than the CN operator.

The MME 162 may be connected to each of the eNode-Bs 162a, 162b, 162c in the RAN 104 via an S1 interface and may serve as a control node. For example, the MME 162 may be responsible for authenticating users of the WTRUs 102a, 102b, 102c, bearer activation/deactivation, selecting a particular serving gateway during an initial attach of the WTRUs 102a, 102b, 102c, and the like. The MME 162 may provide a control plane function for switching between the RAN 104 and other RANs (not shown) that employ other radio technologies, such as GSM and/or WCDMA.

The SGW 164 may be connected to each of the eNode Bs 160a, 160b, 160c in the RAN 104 via the S1 interface. The SGW 164 may generally route and forward user data packets to/from the WTRUs 102a, 102b, 102c. The SGW 164 may perform other functions, such as anchoring user planes during inter-eNode B handovers, triggering paging when DL data is available for the WTRUs 102a, 102b, 102c, managing and storing contexts of the WTRUs 102a, 102b, 102c, and the like.

The SGW 164 may be connected to the PGW 166, which may provide the WTRUs 102a, 102b, 102c with access to packet-switched networks, such as the Internet 110, to facilitate communications between the WTRUs 102a, 102b, 102c and IP-enabled devices.

The CN 106 may facilitate communications with other networks. For example, the CN 106 may provide the WTRUs 102a, 102b, 102c with access to circuit-switched networks, such as the PSTN 108, to facilitate communications between the WTRUs 102a, 102b, 102c and traditional land-line communications devices. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers.

Although the WTRU is described in FIGS. 1A-1D as a wireless terminal, it is contemplated that in certain representative embodiments that such a terminal may use (e.g., temporarily or permanently) wired communication interfaces with the communication network.

In representative embodiments, the other network 112 may be a WLAN.

A WLAN in Infrastructure Basic Service Set (BSS) mode may have an Access Point (AP) for the BSS and one or more stations (STAs) associated with the AP. The AP may have an access or an interface to a Distribution System (DS) or another type of wired/wireless network that carries traffic in to and/or out of the BSS. Traffic to STAs that originates from outside the BSS may arrive through the AP and may be delivered to the STAs. Traffic originating from STAs to destinations outside the BSS may be sent to the AP to be delivered to respective destinations. Traffic between STAs within the BSS may be sent through the AP, for example, where the source STA may send traffic to the AP and the AP may deliver the traffic to the destination STA. The traffic between STAs within a BSS may be considered and/or referred to as peer-to-peer traffic. The peer-to-peer traffic may be sent between (e.g., directly between) the source and destination STAs with a direct link setup (DLS). In certain representative embodiments, the DLS may use an 802.11e DLS or an 802.11z tunneled DLS (TDLS). A WLAN using an Independent BSS (IBSS) mode may not have an AP, and the STAs (e.g., all of the STAs) within or using the IBSS may communicate directly with each other. The IBSS mode of communication may sometimes be referred to herein as an “ad-hoc” mode of communication.

When using the 802.11ac infrastructure mode of operation or a similar mode of operations, the AP may transmit a beacon on a fixed channel, such as a primary channel. The primary channel may be a fixed width (e.g., 20 MHz wide bandwidth) or a dynamically set width via signaling. The primary channel may be the operating channel of the BSS and may be used by the STAs to establish a connection with the AP. In certain representative embodiments, Carrier Sense Multiple Access with Collision Avoidance (CSMA/CA) may be implemented, for example in in 802.11 systems. For CSMA/CA, the STAs (e.g., every STA), including the AP, may sense the primary channel. If the primary channel is sensed/detected and/or determined to be busy by a particular STA, the particular STA may back off. One STA (e.g., only one station) may transmit at any given time in a given BSS.

High Throughput (HT) STAs may use a 40 MHz wide channel for communication, for example, via a combination of the primary 20 MHz channel with an adjacent or nonadjacent 20 MHz channel to form a 40 MHz wide channel.

Very High Throughput (VHT) STAs may support 20 MHz, 40 MHz, 80 MHz, and/or 160 MHz wide channels. The 40 MHz, and/or 80 MHz, channels may be formed by combining contiguous 20 MHz channels. A 160 MHz channel may be formed by combining 8 contiguous 20 MHz channels, or by combining two non-contiguous 80 MHz channels, which may be referred to as an 80 +80 configuration. For the 80 +80 configuration, the data, after channel encoding, may be passed through a segment parser that may divide the data into two streams. Inverse Fast Fourier Transform (IFFT) processing, and time domain processing, may be done on each stream separately. The streams may be mapped on to the two 80 MHz channels, and the data may be transmitted by a transmitting STA. At the receiver of the receiving STA, the above described operation for the 80 +80 configuration may be reversed, and the combined data may be sent to the Medium Access Control (MAC).

Sub 1 GHz modes of operation are supported by 802.11af and 802.11ah. The channel operating bandwidths, and carriers, are reduced in 802.11af and 802.11ah relative to those used in 802.11n, and 802.11ac. 802.11af supports 5 MHz, 10 MHz and 20 MHz bandwidths in the TV White Space (TVWS) spectrum, and 802.11ah supports 1 MHz, 2 MHz, 4 MHz, 8 MHz, and 16 MHz bandwidths using non-TVWS spectrum. According to a representative embodiment, 802.11ah may support Meter Type Control/Machine-Type Communications, such as MTC devices in a macro coverage area. MTC devices may have certain capabilities, for example, limited capabilities including support for (e.g., only support for) certain and/or limited bandwidths. The MTC devices may include a battery with a battery life above a threshold (e.g., to maintain a very long battery life).

WLAN systems, which may support multiple channels, and channel bandwidths, such as 802.11n, 802.11ac, 802.11af, and 802.11ah, include a channel which may be designated as the primary channel. The primary channel may have a bandwidth equal to the largest common operating bandwidth supported by all STAs in the BSS. The bandwidth of the primary channel may be set and/or limited by a STA, from among all STAs in operating in a BSS, which supports the smallest bandwidth operating mode. In the example of 802.11ah, the primary channel may be 1 MHz wide for STAs (e.g., MTC type devices) that support (e.g., only support) a 1 MHz mode, even if the AP, and other STAs in the BSS support 2 MHz, 4 MHz, 8 MHz, 16 MHz, and/or other channel bandwidth operating modes. Carrier sensing and/or Network Allocation Vector (NAV) settings may depend on the status of the primary channel. If the primary channel is busy, for example, due to a STA (which supports only a 1 MHz operating mode), transmitting to the AP, the entire available frequency bands may be considered busy even though a majority of the frequency bands remains idle and may be available.

In the United States, the available frequency bands, which may be used by 802.11ah, are from 902 MHz to 928 MHz. In Korea, the available frequency bands are from 917.5 MHz to 923.5 MHz. In Japan, the available frequency bands are from 916.5 MHz to 927.5 MHz. The total bandwidth available for 802.11ah is 6 MHz to 26 MHz depending on the country code.

FIG. 1D is a system diagram illustrating the RAN 113 and the CN 115 according to an embodiment. As noted above, the RAN 113 may employ an NR radio technology to communicate with the WTRUs 102a, 102b, 102c over the air interface 116. The RAN 113 may also be in communication with the CN 115.

The RAN 113 may include gNBs 180a, 180b, 180c, though it will be appreciated that the RAN 113 may include any number of gNBs while remaining consistent with an embodiment. The gNBs 180a, 180b, 180c may each include one or more transceivers for communicating with the WTRUs 102a, 102b, 102c over the air interface 116. In one embodiment, the gNBs 180a, 180b, 180c may implement MIMO technology. For example, gNBs 180a, 108b may utilize beamforming to transmit signals to and/or receive signals from the gNBs 180a, 180b, 180c. Thus, the gNB 180a, for example, may use multiple antennas to transmit wireless signals to, and/or receive wireless signals from, the WTRU 102a. In an embodiment, the gNBs 180a, 180b, 180c may implement carrier aggregation technology. For example, the gNB 180a may transmit multiple component carriers to the WTRU 102a (not shown). A subset of these component carriers may be on unlicensed spectrum while the remaining component carriers may be on licensed spectrum. In an embodiment, the gNBs 180a, 180b, 180c may implement Coordinated Multi-Point (CoMP) technology. For example, WTRU 102a may receive coordinated transmissions from gNB 180a and gNB 180b (and/or gNB 180c).

The WTRUs 102a, 102b, 102c may communicate with gNBs 180a, 180b, 180c using transmissions associated with a scalable numerology. For example, the OFDM symbol spacing and/or OFDM subcarrier spacing may vary for different transmissions, different cells, and/or different portions of the wireless transmission spectrum. The WTRUs 102a, 102b, 102c may communicate with gNBs 180a, 180b, 180c using subframe or transmission time intervals (TTIs) of various or scalable lengths (e.g., containing varying number of OFDM symbols and/or lasting varying lengths of absolute time).

The gNBs 180a, 180b, 180c may be configured to communicate with the WTRUs 102a, 102b, 102c in a standalone configuration and/or a non-standalone configuration. In the standalone configuration, WTRUs 102a, 102b, 102c may communicate with gNBs 180a, 180b, 180c without also accessing other RANs (e.g., such as eNode-Bs 160a, 160b, 160c). In the standalone configuration, WTRUs 102a, 102b, 102c may utilize one or more of gNBs 180a, 180b, 180c as a mobility anchor point. In the standalone configuration, WTRUs 102a, 102b, 102c may communicate with gNBs 180a, 180b, 180c using signals in an unlicensed band. In a non-standalone configuration WTRUs 102a, 102b, 102c may communicate with/connect to gNBs 180a, 180b, 180c while also communicating with/connecting to another RAN such as eNode-Bs 160a, 160b, 160c. For example, WTRUs 102a, 102b, 102c may implement DC principles to communicate with one or more gNBs 180a, 180b, 180c and one or more eNode-Bs 160a, 160b, 160c substantially simultaneously. In the non-standalone configuration, eNode-Bs 160a, 160b, 160c may serve as a mobility anchor for WTRUs 102a, 102b, 102c and gNBs 180a, 180b, 180c may provide additional coverage and/or throughput for servicing WTRUs 102a, 102b, 102c.

Each of the gNBs 180a, 180b, 180c may be associated with a particular cell (not shown) and may be configured to handle radio resource management decisions, handover decisions, scheduling of users in the UL and/or DL, support of network slicing, dual connectivity, interworking between NR and E-UTRA, routing of user plane data towards User Plane Function (UPF) 184a, 184b, routing of control plane information towards Access and Mobility Management Function (AMF) 182a, 182b and the like. As shown in FIG. 1D, the gNBs 180a, 180b, 180c may communicate with one another over an Xn interface.

The CN 115 shown in FIG. 1D may include at least one AMF 182a, 182b, at least one UPF 184a,184b, at least one Session Management Function (SMF) 183a, 183b, and possibly a Data Network (DN) 185a, 185b. While each of the foregoing elements are depicted as part of the CN 115, it will be appreciated that any of these elements may be owned and/or operated by an entity other than the CN operator.

The AMF 182a, 182b may be connected to one or more of the gNBs 180a, 180b, 180c in the RAN 113 via an N2 interface and may serve as a control node. For example, the AMF 182a, 182b may be responsible for authenticating users of the WTRUs 102a, 102b, 102c, support for network slicing (e.g., handling of different PDU sessions with different requirements), selecting a particular SMF 183a, 183b, management of the registration area, termination of NAS signaling, mobility management, and the like. Network slicing may be used by the AMF 182a, 182b in order to customize CN support for WTRUs 102a, 102b, 102c based on the types of services being utilized WTRUs 102a, 102b, 102c. For example, different network slices may be established for different use cases such as services relying on ultra-reliable low latency (URLLC) access, services relying on enhanced massive mobile broadband (eMBB) access, services for machine type communication (MTC) access, and/or the like. The AMF 162 may provide a control plane function for switching between the RAN 113 and other RANs (not shown) that employ other radio technologies, such as LTE, LTE-A, LTE-A Pro, and/or non-3GPP access technologies such as WiFi.

The SMF 183a, 183b may be connected to an AMF 182a, 182b in the CN 115 via an N11 interface. The SMF 183a, 183b may also be connected to a UPF 184a, 184b in the CN 115 via an N4 interface. The SMF 183a, 183b may select and control the UPF 184a, 184b and configure the routing of traffic through the UPF 184a, 184b. The SMF 183a, 183b may perform other functions, such as managing and allocating WTRU IP address, managing PDU sessions, controlling policy enforcement and QoS, providing downlink data notifications, and the like. A PDU session type may be IP-based, non-IP based, Ethernet-based, and the like.

The UPF 184a, 184b may be connected to one or more of the gNBs 180a, 180b, 180c in the RAN 113 via an N3 interface, which may provide the WTRUs 102a, 102b, 102c with access to packet-switched networks, such as the Internet 110, to facilitate communications between the WTRUs 102a, 102b, 102c and IP-enabled devices. The UPF 184, 184b may perform other functions, such as routing and forwarding packets, enforcing user plane policies, supporting multi-homed PDU sessions, handling user plane QoS, buffering downlink packets, providing mobility anchoring, and the like.

The CN 115 may facilitate communications with other networks. For example, the CN 115 may include, or may communicate with, an IP gateway (e.g., an IP multimedia subsystem (IMS) server) that serves as an interface between the CN 115 and the PSTN 108. In addition, the CN 115 may provide the WTRUs 102a, 102b, 102c with access to the other networks 112, which may include other wired and/or wireless networks that are owned and/or operated by other service providers. In one embodiment, the WTRUs 102a, 102b, 102c may be connected to a local Data Network (DN) 185a, 185b through the UPF 184a, 184b via the N3 interface to the UPF 184a, 184b and an N6 interface between the UPF 184a, 184b and the DN 185a, 185b.

In view of FIGS. 1A-1D, and the corresponding description of FIGS. 1A-1D, one or more, or all, of the functions described herein with regard to one or more of: WTRU 102a-d, Base Station 114a-b, eNode-B 160a-c, MME 162, SGW 164, PGW 166, gNB 180a-c, AMF 182a-ab, UPF 184a-b, SMF 183a-b, DN 185a-b, and/or any other device(s) described herein, may be performed by one or more emulation devices (not shown). The emulation devices may be one or more devices configured to emulate one or more, or all, of the functions described herein. For example, the emulation devices may be used to test other devices and/or to simulate network and/or WTRU functions.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or may performing testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

A WTRU may receive configuration information, for example from a network (NW). The configuration information may include an indication of a hybrid automatic request (HARQ) feedback report type and/or an HARQ feedback report format. The WTRU may receive, from the network, a downlink (DL) scheduling message and/or a DL transmission associated with the DL scheduling message (e.g., scheduled by the DL scheduling message). The WTRU may determine one or more decoding parameters, for example based on the DL transmission. The one or more decoding parameters may include one or more of a soft combining feedback message, a decoding feedback message, a cyclic redundancy check (CRC) feedback message, a (e.g., requested) MCS, a new data indicator (NDI), a code block group transmission information (CBGTI), and/or a code block group flushing out information (CBGFI). The WTRU may determine the HARQ feedback report type, the HARQ feedback report format, and/or the HARQ feedback report, for example based on the configuration information and/or the one or more decoding parameters. The WTRU may send the HARQ feedback report, for example to the network.

The WTRU may generate the HARQ feedback report based on one or more of the decoding parameters, the DL transmission, and/or the DL scheduling message. The HARQ feedback report may be associated with the HARQ feedback report type and/or the HARQ feedback report format. The HARQ feedback report may include an indication of at least one of a log-likelihood ratio (LLR) of coded bits associated with the soft combining feedback message, a decoding complexity associated with the downlink transmission, and/or cyclic redundancy check (CRC) bits associated with the CRC feedback message. The HARQ feedback report format may include an explicit indication or a latent representation for the HARQ feedback report.

The downlink scheduling message may include one or more of a modulation and coding scheme (MCS), a data allocation associated with one or more transport blocks (TBs), a HARQ process identifier (ID) associated with the one or more TBs, code block group (CBG) transmission information (CBGTI), and/or CBG flushing out information (CBGFI) associated with the CBG. The soft combining feedback message may include an indication of one or more of a log likelihood ratios (LLR) and/or a signal to interference plus noise ratio (SINR). The decoding feedback message may include an indication of forward error correction (FEC). The CRC feedback message may include an indication of at least one of a cyclic redundancy check (CRC), an acknowledgment (ACK), and/or a non-acknowledgment (NACK).

The WTRU may receive a request to transmit HARQ feedback capabilities to the network. The WTRU may transmit the HARQ feedback capabilities to the network, for example in response to the request. The HARQ feedback capabilities may include an indication that the WTRU supports artificial intelligence/machine learning (AI/ML) HARQ feedback. The WTRU may receive an AI/ML model for HARQ feedback.

The HARQ feedback report comprises an indication of one or more of log-likelihood ratio (LLR) of the coded bits from the soft combining feedback message, a decoding complexity associated with the downlink transmission from the decoding feedback message, and/or the reconstructed data and CRC bits from the CRC feedback message. The soft combining feedback message may include information about the soft combining operation at the WTRU (e.g., statistics of log likelihood ratios (LLRs) after soft combining, resulting signal to interference plus noise ratio (SINR) after soft combining, etc.). The decoding feedback message may include information and/or statistics about the forward error correction (FEC) decoding process at the WTRU (e.g., the number of iterations that the FEC decoder used to decode the resulting LLRs). The CRC feedback message may include information about the CRC validation process at the WTRU (e.g. ACK/NACK bits, total set of CRC bits after CRC validation). The WTRU may determine the HARQ feedback report based on one or more of the soft combining feedback message, the decoding feedback message, the cyclic redundancy check (CRC) feedback message, the requested MCS, the NDI, the CBGTI, and/or the CBGFI. The WTRU may send the HARQ feedback report, the HARQ feedback report type, and/or the HARQ feedback report format, for example to the network.

The WTRU may determine the HARQ feedback report based on one or more function parameter of an artificial intelligence/machine learning (AI/ML)-based function. The one or more function parameter may be based on the one or more decoding parameters, a modulation and coding scheme (MCS), a new data indicator (NDI), a code block group transmission information (CBGTI), and/or a code block group flushing out information (CBGFI). The WTRU may determine the HARQ feedback report based on an artificial intelligence/machine learning (AI/ML) compression rate.

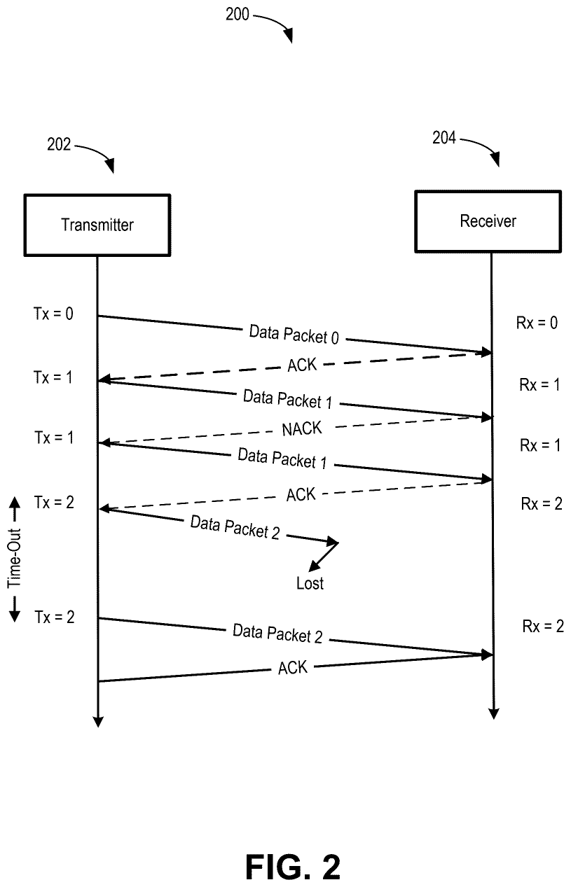

Systems and methods may include ARQ protocol. FIG. 2 is an example of ARQ protocol 200. ARQ protocol may be used in data communication, for example to ensure reliable data transmission. Systems and methods for ARQ protocol may include a transmitter 202 transmitting data packets and/or a receiver 204 checking for errors. If a packet is received with error(s) or is not received at all for example, the receiver 204 may request that the transmitter 202 retransmits the missing and/or erroneous packet (e.g., packet with error(s)). ARQ protocol may utilize error detection (e.g., an error detection mechanism), for example to check whether the received data is in error.

Error detection may include cyclic redundancy check (CRC). For example, error detection code may include CRC code. If no error is detected in the received data for example, the receiver 204 may notify the transmitter 202 by sending an acknowledgement (ACK). If an error is detected in the received data for example, the receiver 204 may discard the received data and/or notify the transmitter 202/network (NW). For example, the receiver 204 may notify the transmitter 202/network by sending a negative acknowledgement (NACK). In response, for example, the transmitter 202 may retransmit the (e.g., same) information. The receiver may include for example a WTRU and/or a network. The transmitter may include a network and/or a WTRU.

There may be variations of ARQ. For example, there may be stop-and-wait ARQ. In stop-and-wait ARQ for example, the transmitter 202 may send a data packet to the receiver 204. The transmitter 202 may keep (e.g., store) a copy of the transmitted data packet and/or may stop and wait for an ACK for the transmitted data packet, for example before sending any new data packets. If the transmitter 202 does not receive an ACK within a (e.g., predetermined) timeframe and/or receives a NACK for example, the transmitter 202 may retransmit the (e.g., same) data packet.

There may be forward error correction (FEC). FEC may be utilized to detect and/or correct errors, for example that occur during data transmission and/or storage. FEC may enable reliable communication and/or data integrity, for example in noisy environments. Errors in communication systems may occur due to various reasons, for example, including noise, interference, and/or hardware malfunctions. FEC may improve data reliability in communication systems by adding redundancy to the transmitted data. The redundancy may allow the receiver to identify and/or correct errors that may have occurred during transmission.

FEC codes may encode original data with additional bits (e.g., redundancy). The encoded data may (e.g., then) be sent over the channel. The receiver may utilize the extra bits to check for and/or correct errors. FEC may be used to ensure that the original data may be recovered, for example if some bits are corrupted. Examples of FEC codes include low-density parity-check (LDPC) codes, block codes (e.g., Reed-Muller codes, and/or polar codes), convolutional codes, and/or turbo codes, etc.

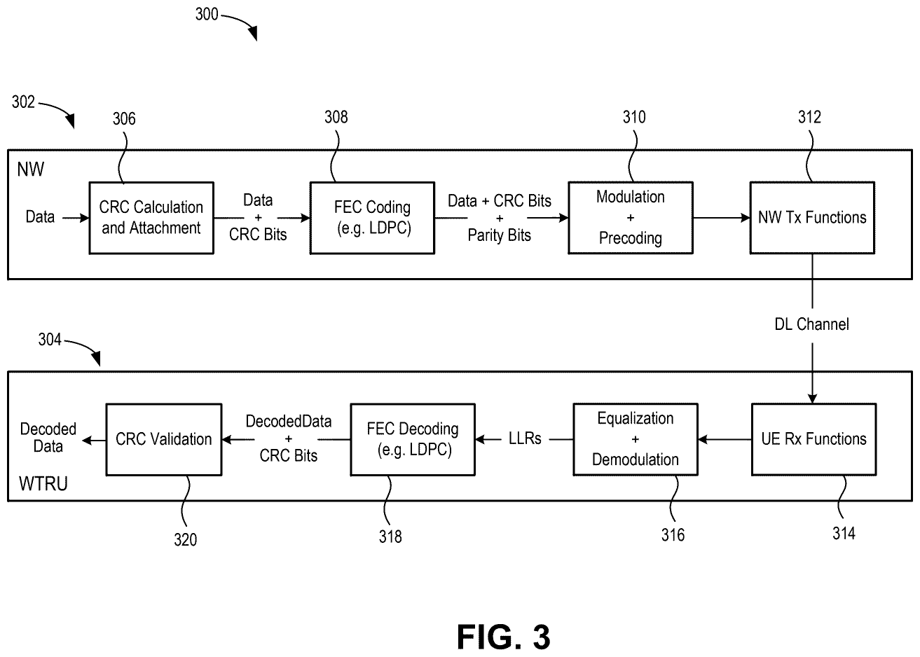

Systems and methods may include hybrid automatic repeat request (HARQ) protocol. HARQ protocol may include a combination of ARQ protocol and FEC. FIG. 3 is an example of an HARQ protocol 300. HARQ protocol may enhance ARQ, for example by combining error correction and retransmission. Enhanced HARQ protocol may be utilized in a 5G NR system and/or may include an HARQ protocol which integrates the HARQ protocol with packet combining. If a received signal has led to a detection failure for example, the signal may include useful information about the transmitted packet. Using HARQ protocol for example, the receiver may retain the erroneous data packets and/or request retransmission of corrupted packets. The receiver may (e.g., then) combine the retained erroneous blocks with a new retransmission(s), which for example may result in a higher chance of successful packet decoding and/or an enhanced detection performance.

A network 302 may utilize data for example in a CRC calculation and/or attachment at 306. The CRC calculation and/or attachment at 306 may output data and/or CRC bits. At 308 FEC coding (e.g., LDPC) may utilize the data and/or CRC bits to output data, CRC bits, and/or parity bits. The data, CRC bits, and/or parity bits may be input to modulation and/or precoding at 310. At 312, the network 302 may (e.g., then) transmit the resulting data, CRC bits, and/or parity bits after modulation an/or precoding to a WTRU 304 using, for example, the network transmission (Tx) function(s).

The WTRU 304 may receive the data, CRC bits, and/or the parity bits from the NW 302, for example via a downlink (DL) channel. The WTRU 304 may perform receiver (Rx) function(s) at 314. The WTRU 304 may (e.g., then) perform equalization and/or demodulation at 316. Equalization and/or demodulation may output LLRs. The LLRs may be input for the WTRU to perform FEC decoding (e.g., LDPC) at 318. The FEC decoding may output decoded data and/or CRC bits. The WTRU 304 may perform CRC validation at 320, for example using the decoded data and/or CRC bits. The CRC validation (e.g., at 320) may output decoded data.

Systems and methods may include soft combining. Soft combining may include receiver combining retransmitted data with (e.g., previously) received data, for example that was not correctly decoded. Soft combining may improve (e.g., overall) reliability of data, for example by utilizing information which may be included in erroneous transmissions. Soft combining may include chase combining and/or incremental redundancy.

Chase combining may include a physical layer applying a (e.g., same) puncturing pattern to (e.g., both) the original transmission and/or a (e.g., each) retransmission. Chase combining may result in retransmission(s), for example including the same set of physical layer bits as a previous (e.g., original) transmission. A systematic bit may remain the same, for example in a subsequent transmission.

Incremental redundancy may include a physical layer applying different puncturing pattern(s) to (e.g., both) the original transmission and/or retransmission. Incremental redundancy may result in a retransmission, for example including a different set of physical layer bits to a previous (e.g., original) transmission. A (e.g., first) transmission may provide systematic bits with the greatest priority. Subsequent retransmissions may provide (e.g., either) the systematic bits and/or parity bits with the greatest priority (e.g., parity 1 and/or parity 2 bits). 5G NR systems may utilize channel quality indicator (CQI). CQI may include a metric that may assess the quality of a communication channel between a WTRU and a network. For example, quality may be assessed in terms of signal strength, noise levels, and/or interference. Additionally, or alternatively, quality may be assessed to configure and/or adjust data transmission parameters, for example modulation and coding schemes.

CQI may be on periodic measurements, which for example may not reflect real-time channel conditions. Rapid changes in the wireless channel and/or WTRU mobility may lead to outdated CQI values, that for example may not reflect the instantaneous channel conditions at the time of data transmission. 5G NR systems may utilize HARQ protocol, for example to ensure the reliability and/or the integrity of data reception. HARQ protocol may ensure reliability and/or integrity of data reception by utilizing error detection mechanisms, correction mechanisms, retransmissions, and/or combining retransmissions (e.g., soft combining).

An HARQ feedback mechanism may be used for ACK/NACK reporting from the WTRU, for example for each code block group (CBG). Feedback may not be sufficient for the NW to efficiently handle the retransmissions, for example to meet the target block error rate (BLER) (e.g., best modulation and coding scheme (MCS), and/or best redundancy version, etc.). Systems and methods that enable the WTRU to generate an HARQ feedback report including more information and/or enabling the NW to design a better transmission and/or retransmission strategy (e.g., MCS, transport block size and/or redundancy version, etc. for the DL transmission) for example that meets a target BLER based on the HARQ feedback report generated by the WTRU, may be desirable.

Systems and methods for enhanced HARQ feedback are disclosed herein, for example an enhanced HARQ feedback mechanism. The WTRU may generate an HARQ feedback report that is more informative than the legacy HARQ feedback and/or to transmit the HARQ feedback report to the NW. The NW may decide the best transmission and/or retransmission strategy (e.g., MCS, transport block size and/or redundancy version, etc.), for example based on the HARQ feedback report received from the WTRU. The redundancy version (RV) index effectively determines the bit selection offset from the rate matching buffer (also known as the circular buffer). First, the WTRU employs an HARQ feedback generation function to generate an HARQ feedback report that includes multiple information that the WTRU can provide to assist the NW in deciding the best transmission or retransmission strategy. Second, the NW employs an HARQ processing function to decide the appropriate transmission or retransmission strategy (e.g., MCS, transport block size, redundancy version, etc.) that meets the target BLER using the HARQ feedback report received from the WTRU.

The WTRU may perform enhanced HARQ feedback reporting, for example as described herein. NW as herein may refer to any node in the network, for example a base station (e.g., gNB), a WTRU (e.g., sidelink, WTRU-to-WTRU direct communication), etc. A WTRU may receive (e.g., from NW) a request to transmit HARQ feedback capabilities. The WTRU may transmit one or more HARQ feedback capabilities (e.g., message), for example to the NW. The HARQ feedback capabilities message may indicate one or more of WTRU support for AI/ML-based HARQ feedback reporting, WTRU receiver (e.g., channel estimation, equalization, symbol demodulation, and/or channel decoding, etc.) and/or soft combining capabilities, and/or WTRU hardware/radio impairments (e.g., phase noise characteristic, power amplifier characteristic, etc.). WTRU receiver (e.g., channel estimation, equalization, symbol demodulation, and/or channel decoding, etc.) and/or soft combining capabilities may include WTRU support for AI/ML-based receiver functions and/or WTRU support for AI/ML-based soft combining functions.

The WTRU may transmit the HARQ feedback capabilities (e.g., to the NW) via RRC signaling. The WTRU may receive (e.g., from NW) an artificial intelligence/machine learning (AI/ML) model for an HARQ feedback generation function if the WTRU supports AI/ML-based HARQ feedback reporting. The WTRU may receive (e.g., from the NW) a DL scheduling message and/or a configuration message for HARQ feedback reporting. The DL scheduling message may include data allocation(s) of one or more transport blocks (TBs), an HARQ process identifier (ID) of a (e.g., each) TB, a CBG transmission information (CBGTI), and/or CBG flushing out information (CBGFI) for a (e.g., each) CBG (e.g., if data transmission is based on CBGs). The configuration message for HARQ feedback reporting may include one or more of a HARQ feedback report type (e.g., whether the HARQ feedback report includes soft combining feedback message, decoding feedback message, CRC feedback message, requested DL MCS, NDI, CBGTI, and/or CBGFI, etc.) for use in the HARQ feedback report, a HARQ feedback report format (e.g., explicit or latent representation), and/or an uplink transmission mechanism for the HARQ feedback report. The HARQ feedback report may be transmitted on physical uplink shared channel (PUSCH), physical uplink control channel (PUCCH) or medium access control-control element (MAC-CE). The uplink transmission mechanism for the HARQ feedback report may include transmission scheme on PUSCH (for example, multiplexing, interleaving, rate matching of HARQ feedback payload bits and data bits) and transmission scheme on PUCCH (for example, PUCCH resource mapping allocation and mapping rule for corresponding downlink data transmission, modulation and coding scheme for the HARQ feedback and etc.).

When the HARQ feedback report format is a latent representation for example, the configuration message may include a size of the latent representation (e.g., number of latent variables) and/or a configuration of the quantization operation to be applied to the latent representation. The configuration of the quantization operation to be applied to the latent representation may include the number of bits per latent variable, uniform/non-uniform quantization, and/or scalar/vector quantization, etc.

The WTRU may receive the DL scheduling message, for example through DCI. The WTRU may receive the configuration message, for example via DCI, MAC-CE, and/or RRC signaling. The WTRU may receive DL data (e.g., transport blocks, multiple code blocks, and/or code block groups (CBGs), etc.). The WTRU may pass (e.g., input) the received DL data through the WTRU receiver (e.g., channel estimation, equalization, demodulation, etc.) and/or soft combining function.

The WTRU may decode the received DL data and/or determine one or more decoding parameters, for example based on the decoding process. The one or more decoding parameters may include a soft combining feedback message (e.g., from the soft combining function), a decoding feedback message, and/or a CRC feedback message. The soft combining feedback message (e.g., from the soft combining function) may be based on log-likelihood-ratios (LLRs) of the coded bits. The soft combining function may include a non-AI/ML function (e.g., legacy soft combining technique) and/or an AI/ML-based function (e.g., a neural network). If the soft combining function includes a non-AI/ML function for example, the soft combining feedback message may be explicit and/or may include statistics of the output LLRs, and/or resulting SINR after soft combining, etc. For example, the resulting SINR may include the difference between the resulting SINR after soft combining and an estimated SINR that the network (e.g., gNB) determined (e.g., assumed) when scheduling the transmission. The WTRU may determine (e.g., infer) the signal to noise ratio (SNR) that the NW determines (e.g., assumes) the WTRU is experiencing, for example based on the CQI-to-MCS mapping or SNR-to-MCS mapping. The WTRU may determine the SNR for example based on (e.g., knowing) the MCS used in a downlink transmission.

If the soft combining function is an AI/ML-based function for example, the soft combining function may be designed either separately or jointly with the receiver functions (e.g., channel estimation, equalization, and/or demodulation, etc.). If the soft combining function is an AI/ML-based function that is designed jointly with the receiver functions for example, the WTRU may include a (e.g., single) AI/ML-based receiver and/or soft combining function. The AI/ML-based receiver and/or soft combining function may include other WTRU receiver functions (e.g., channel estimation, equalization, and/or demodulation, etc.) and/or the soft combining function. The WTRU may input the received DL data to the AI/ML-based function and/or output the LLRs of the coded bits transmitted by the NW. The WTRU may input previously generated LLRs to the AI/ML-based receiver and/or soft combining function. The soft combining feedback message may include a latent feedback message (e.g., a latent representation).

The one or more decoding parameters may include a decoding feedback message. The decoding feedback message may include measured statistics of decoding complexity, for example the number of iterations that the FEC decoder used to decode the resulting LLRs. The one or more decoding parameters may include a CRC feedback message. The CRC feedback message may include an explicit or a latent feedback message (e.g., a learnable feedback message). The CRC feedback message may include the total set of CRC bits.

The WTRU may determine an HARQ feedback report type, an HARQ feedback report format, and/or an HARQ feedback report, for example based on the received configuration message, the received DL data, the one or more determined decoding parameters, and/or the performance of the HARQ feedback generation function (e.g., AIML compression rate). The WTRU may input the decoding parameters to an HARQ feedback generation function and/or generate an HARQ feedback report.

The HARQ feedback report may include an explicit feedback report or a latent feedback report, that for example is learnable (e.g., output of an AI/ML model). If the HARQ feedback report includes a latent feedback report for example, the HARQ feedback generation function at the WTRU may include an AI/ML model. The WTRU may input the decoding parameters, for example with the previously generated HARQ feedback reports to the AI/ML model and/or may generate an HARQ feedback report. The HARQ feedback report may be generated in the form of a compressed/latent representation.

The WTRU may adjust the parameters of the AI/ML-based HARQ feedback generation function (e.g., size of the latent representation), for example based on the decoding parameters. For example, the NW may configure the WTRU with a certain HARQ feedback payload size. The WTRU may select a different size for the output latent representation and/or may select a subset of the decoding parameters to be reported to the NW, for example as a function of the decoding parameters. The WTRU may report (e.g., this feedback size adjustment behavior) to the NW. The WTRU may transmit the HARQ feedback report, for example using configured HARQ feedback report transmission parameters. Additionally, or alternatively, the WTRU may transmit the determined HARQ feedback report type and/or the HARQ feedback report format.

The NW may transmit an HARQ feedback capabilities request, for example to the WTRU. The NW may receive the WTRU HARQ feedback capabilities, for example from the WTRU. The NW may determine and/or transmit an (e.g., appropriate) AI/ML model for the HARQ feedback generation function to the WTRU, for example if the WTRU supports AI/ML-based HARQ feedback reporting.

The NW may transmit a configuration message to the WTRU. The NW may transmit the DL data, to the WTRU. The NW may receive an HARQ feedback report type, an HARQ feedback report format, and/or an HARQ feedback report. The NW may determine and/or extract the HARQ feedback report, for example from the received UL signal(s) (e.g., performing channel estimation, equalization, demodulation, and/or channel decoding, etc.). The NW may input the extracted HARQ feedback report with the (e.g., available) received CSI feedback reports (e.g., associated with prior DL channel sounding operations) to the NW HARQ processing function. The NW may reconstruct the ACK/NACK feedback associated with the DL transmitted TBs and/or CBGs (e.g., if data retransmission is based on CBGs). The NW may generate a transmission or retransmission (Tx/ReTx) recommendation. The transmission or retransmission recommendation may include a DL MCS, a predicted number of retransmissions for the generated MCS, and/or a redundancy version, etc.

Systems and methods may include enhanced HARQ feedback, for example an enhanced HARQ feedback mechanism. The WTRU may generate an HARQ feedback report that is more informative than legacy HARQ feedback and/or may transmit the HARQ feedback report to the NW. The NW may decide the best transmission and/or retransmission strategy (e.g., MCS, and/or redundancy version, etc.), for example based on the HARQ feedback report received from the WTRU.

The WTRU may use an HARQ feedback generation function for example to generate an HARQ feedback report. The HARQ feedback report may include information that the WTRU may provide to assist the NW in deciding the best transmission and/or retransmission strategy. The NW may use an HARQ processing function for example to determine a (e.g., appropriate) transmission and/or retransmission strategy (e.g., MCS, redundancy version, etc.). The NW may determine transmission and/or retransmission strategy that meets a target BLER, for example based on the HARQ feedback report received from the WTRU.

The WTRU may receive a DL scheduling message (e.g., configuration message from the NW). The DL scheduling message may indicate data allocation(s) of one or more transport blocks (TBs), an HARQ process of a (e.g., each) transport block (TB), a new data indicator (NDI) of a (e.g., each) TB, and/or a CBGTI and/or CBGFI for a (e.g., each) CBG (e.g., if data transmission is based on CBGs).

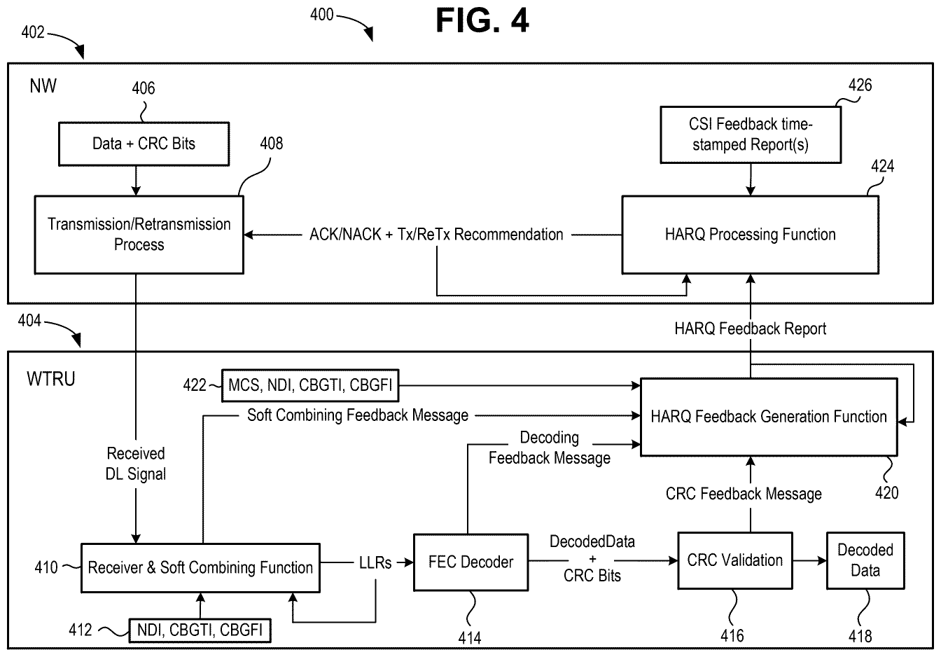

FIG. 4 is an example of enhanced HARQ feedback 400. A WTRU 404 may receive a DL data from a NW 402. The WTRU 404 may input the DL data to a receiver (e.g., channel estimation, equalization, and/or demodulation, etc.) and/or soft combining function at 410. The WTRU 404 may generates log-likelihood-ratios (LLRs) of the coded information bits transmitted by the NW 402, for example with the receiver and/or soft combining function at 410. If NDI is toggled for example (e.g., 412), the WTRU 404 may flush out the soft buffer (e.g., before loading the generated LLRs). If the NDI is not toggled for example (e.g., at 412), the WTRU 404 may apply soft combining between the generated LLRs and/or the retained LLRs in the soft buffer, and/or generate the resulting LLRs after soft combining.

If data transmission is based on CBGs for example, the WTRU 404 may read the CBGTI parameters (e.g., at 412) and/or may determine which CBGs are present in the DL transmission based on (e.g., by reading) the CBGTI parameters. The WTRU 404 may use (e.g., read) the CBGFI parameters (e.g., at 412) and/or may determine whether the soft buffer containing the CBGs indicated by the CBGTI parameters should be flushed out and/or whether soft combining should be performed. For a (e.g., each) CBG indicated in CBGTI and/or determined to go through soft combining for example, the WTRU 404 may apply soft combining between the generated LLRs and the retained LLRs in the soft buffer of the CBG and/or may generate the resulting LLRs (e.g., after soft combining for that CBG). The WTRU 404 may generate a soft combining feedback message from the soft combining function that provides information about the operation and/or the output of soft combining, for example whether the data transmission is based on TBs and/or CBGs.

The soft combining function may include a non-AI/ML function (e.g., legacy soft combining technique) and/or an AI/ML-based function (e.g., a neural network). If the soft combining function includes a non-AI/ML function for example, the soft combining feedback message may be explicit (e.g., statistics of the output LLRs, and/or resulting signal to interference plus noise ratio (SINR) after soft combining, etc.). If the soft combining function includes an AI/ML-based function for example, the soft combining feedback message may be designed separately or jointly with the receiver functions (e.g., channel estimation, equalization, and/or demodulation, etc.).

The WTRU may include a (e.g., one single) AI/ML-based receiver and soft combining function, for example including the WTRU receiver functions (e.g., channel estimation, equalization, and/or demodulation, etc.) and the soft combining function. The WTRU 404 may input the received DL data to the AI/ML-based function and/or output the LLRs of the coded bits transmitted by the NW 402. Additionally, or alternatively, the WTRU may input (e.g., previously) generated LLRs to the AI/ML-based receiver and soft combining function. The soft combining feedback message may include latent feedback (e.g., a latent representation).

At 414 the WTRU 404 may apply FEC decoding to the resulting LLRs and/or generate decoded data and/or CRC bits, for example associated with the transmitted TBs and/or CBGs. At 414 (e.g., during FEC decoding) the WTRU 404 may generate a decoding feedback message. The decoding feedback message may include statistics about the FEC decoding process (e.g., the number of iterations that the FEC decoder used to decode the resulting LLRs). The information (e.g., statistics) may be used to reveal the complexity of data decoding (e.g., the ease or difficulty of decoding the resulting soft bits). At 416 the WTRU 404 may apply CRC validation, for example to the decoded data and/or CRC bits. At 416 the WTRU 404 may apply CRC validation to check whether the hard bits of the TBs and/or CBGs, and/or the output of the FEC decoder, are correctly decoded.

In the CRC validation operation at 416, the WTRU 404 may generate a CRC feedback message. Additionally, or alternatively at the CRC validation operation at 416, the WTRU 404 may generate decoded data at 418. The CRC feedback message may include ACK/NACK bits, a set of CRC bits, for example a total set of CRC bits. This CRC feedback message may be used to predict a number of retransmissions (e.g., required), for example from the CRC error history from earlier iterations (e.g., how close the WTRU was to decoding the TBs and/or the CBGs successfully). At 420 the WTRU 404 may generate the HARQ feedback report, for example based on one or more inputs and/or using the HARQ feedback generation function. The one or more inputs may include the CRC feedback message (e.g., from CRC validation at 416), the decoding feedback message (e.g., from FEC decoder at 414), the soft combining feedback message (e.g., from the receiver and/or soft combining function at 410), and/or MCS, NDI, CBGTI, and/or CBGFI (e.g., from 422).

The configuration message received from the NW 402 may include commands for generating and/or transmitting the HARQ feedback report. The configuration message may include the decoding parameters (e.g., soft combining feedback message, decoding feedback message, CRC feedback message, requested DL MCS, NDI, CBGTI, and/or CBGFI, etc.), that for example may be included in the HARQ feedback report, the signals and/or the uplink (UL) resource configuration/allocations that may carry the HARQ feedback report, and/or a MCS and/or UL precoder to be applied to the HARQ feedback report (e.g., prior to UL transmission), etc. The WTRU 404 may input the configured feedback messages to a WTRU HARQ feedback generation function to generate an HARQ feedback report and/or may transmit the HARQ feedback report to the NW 402.

The NW 402 may receive the HARQ feedback report. The NW 402 may input the received HARQ feedback report and/or available received CSI feedback reports (e.g., associated with prior DL channel sounding operations) to an HARQ processing function at 424. The NW 402 HARQ processing function may reconstruct the ACK/NACK feedback associated with the DL transmitted TBs and/or CBGs (e.g., if data transmission is based on CBGs).

The NW 402 may generate a transmission and/or retransmission (Tx/ReTx) recommendation. The Tx/ReTx recommendation may include MCS, a predicted number of retransmissions for the generated MCS, a redundancy version, and/or a predicted number of retransmissions, etc. Additionally, or alternatively, the NW 402 may, at 426, input CSI feedback time-stamped report(s) to the HARQ processing function and/or determine the ACK/NACK feedback and/or Tx/ReTx recommendation based on the CSI feedback time-stamped report(s). At 408 the NW 402 may perform a transmission and/or retransmission process, for example to the WTRU 404. The transmission and/or retransmission process (e.g., at 408) may be based on the ACK/NACK feedback, the Tx/ReTx recommendation, and/or data and/or CRC bits (e.g., from 406).

The NW 402 may configure the WTRU 404 to include the decoding parameters (e.g., soft combining feedback message, decoding feedback message, CRC feedback message, and/or requested DL MCS, NDI, CBGTI, and/or CBGFI, etc.), for example depending on the NW 402 and/or WTRU 404 capabilities. The NW 402 may additionally, or alternatively, include decoding parameters explicitly or in the form of a latent representation in the HARQ feedback report. The HARQ feedback report may be learnable (e.g., output of an AI/ML model), for example if the HARQ feedback report is based on a latent representation. The HARQ feedback generation function at the WTRU 404 may be an AI/ML model and/or the WTRU 404 may input the feedback messages to the AI/ML model, for example to generate an HARQ feedback report in the form of a compressed/latent representation.

The WTRU 404 may additionally or alternatively input the previously generated HARQ feedback reports to the HARQ feedback generation function. The configuration message received from the NW 402 may additionally or alternatively include the size of the latent representation (e.g., number of latent variables), and/or a specific quantization operation to be applied to the latent representation (e.g., number of bits per latent variable, uniform/non-uniform quantization, and/or scalar/vector quantization, etc.), etc. The WTRU 404 may (e.g., then) map the generated HARQ feedback report to the configured UL resources and/or transmit the HARQ feedback report to the NW 402.

The WTRU 404 may adjust the parameters of the AI/ML model (e.g., size of the latent representation), for example based on the feedback messages. For example the NW 402 may configure the WTRU 404 with a (e.g., certain) feedback payload size. The WTRU 404 may select a different size for the output latent representation and/or may select a subset of the feedback messages to be reported to the NW 402, for example based on (e.g., as a function of) the feedback messages. The WTRU 404 may report its behavior to the NW 402.

The HARQ processing function (e.g., at 424) of the NW 402 may include an AI/ML model. The NW 402 may input the received HARQ feedback report to the AI/ML model, for example to reconstruct the ACK/NACK feedback associated with the DL transmitted TBs and/or CBG (e.g., if data transmission is based on CBGs). The NW 402 may (e.g., then) generate a Tx/ReTx recommendation.

A WTRU may be configured for AI/ML model enhanced HARQ feedback reporting. Systems and methods herein may include AI/ML HARQ feedback reporting. There may be input data to the AI/ML model. The input data to AI/ML model may include a soft combining feedback message, a decoding feedback message, a CRC feedback message, a (e.g., requested) DL MCS, a NDI, a CBGTI, and/or a CBGFI. The soft combining feedback message may be explicit (e.g., statistics of the output LLRs, and/or resulting SINR after soft combining, etc.) or a latent representation (e.g., a vector and/or tensor of real and/or binary values), for example if the neural receiver and/or the soft combining functions are AI/ML-based functions).

The decoding feedback message may be explicit (e.g., number of iterations that the FEC decoder used to decode the LLRs) or a latent representation (e.g., a vector and/or tensor of real and/or binary values), for example if the FEC decoder at the WTRU is an AI/ML-based function. The CRC feedback message may include ACK/NACK bits and/or a subset or a total set of CRC bits. The (e.g., requested) DL MCS may include DL MCS requested by the WTRU, for example based on DL RS measurements. The WTRU may perform preprocessing. For example the preprocessing may include resizing input data shape and/or normalization.

Output data may include ACK/NACK feedback associated with the DL transmitted TBs and/or CBGs (e.g., if data transmission is based on CBGs), and/or a Tx/ReTx recommendation. The Tx/ReTx recommendation may include DL MCS, a predicted number of retransmissions for the generated MCS, and/or a redundancy version, etc. Training may be performed online using end-to-end learning approaches, for example jointly at the WTRU and the NW.

The WTRU may be configured, for example by the NW, to perform enhanced HARQ feedback. For example parameters may be configured (e.g., by the NW). The parameters may include data allocations of one or more transport blocks (TBs), an HARQ process ID of a (e.g., each) TB, a CBGTI and CBGFI for a (e.g., each) CBG (e.g., if data transmission is based on CBGs), an HARQ feedback report type (e.g., soft combining feedback message, decoding feedback message, CRC feedback message, and/or requested DL MCS, NDI, CBGTI, and/or CBGFI, etc.) to be used in the HARQ feedback report, an HARQ feedback report format (e.g., explicit or a latent representation), MCS and/or UL precoder to be applied to the HARQ feedback report, and/or signals and/or the UL resource configuration/allocations that may carry the HARQ feedback report (e.g., PUSCH, PUCCH, RRC, UCI, and/or MAC-CE). If the HARQ feedback report includes a latent representation for example, the configuration message may include a size of the latent representation (e.g., number of latent variables) and/or a configuration of the quantization operation to be applied to the latent representation. The configuration of the quantization operation to be applied to the latent representation may include the number of bits per latent variable, uniform/non-uniform quantization, and/or scalar/vector quantization, etc.

Systems and methods may include signaling, for example for enhanced HARQ feedback. Signaling may include the HARQ feedback report (e.g., transmitted from the WTRU to the NW), and/or the HARQ feedback report type and/or the HARQ feedback report format (e.g., transmitted from the WTRU to the NW). The HARQ feedback report may include an explicit feedback report or a latent feedback report (e.g., learnable and/or an output of an AI/ML model). The HARQ feedback generation function at the WTRU may include an AI/ML model, for example if the HARQ feedback report includes a latent feedback report.

The WTRU may input the decoding parameters and/or previously generated HARQ feedback reports to the AI/ML model and/or generate an HARQ feedback report in the form of a compressed/latent representation, for example if the HARQ feedback report includes a latent feedback report. The WTRU may transmit the HARQ feedback report, for example using configured HARQ feedback report transmission parameters.

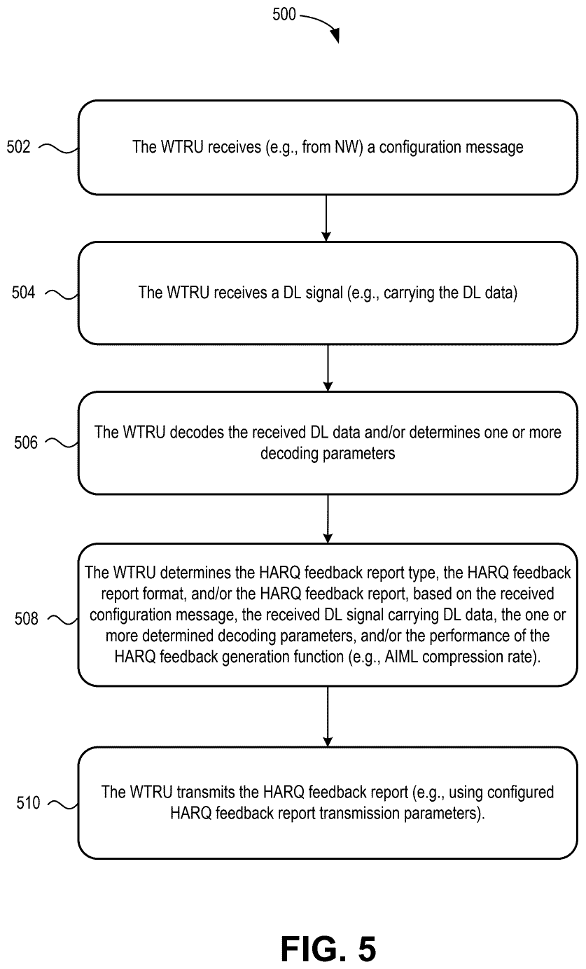

Systems and methods for enhanced HARQ feedback reporting are disclosed herein. FIG. 5 is an example procedure for enhanced HARQ feedback 500. NW as herein may refer to any node in the network, for example an access network, base station, gNB, and/or a (e.g., another) WTRU (e.g., sidelink, and/or WTRU-to-WTRU direct communication), etc. The WTRU may receive (e.g., from a NW) a request to transmit HARQ feedback capabilities. The WTRU may transmit the HARQ feedback capabilities to the NW, for example in response to the request.

The capabilities message may indicate WTRU support for AI/ML-based HARQ feedback reporting, a WTRU receiver and/or soft combining capabilities, and/or WTRU hardware/radio impairments. The WTRU receiver (e.g., channel estimation, equalization, symbol demodulation, channel decoding, etc.) and/or soft combining capabilities may include WTRU support for AI/ML-based receiver functions and/or WTRU support for AI/ML-based soft combining functions. WTRU hardware/radio impairments may include a phase noise characteristic, and/or power amplifier characteristic, etc. The WTRU may transmit WTRU capabilities to the NW, for example by RRC signaling.

The WTRU may receive (e.g., from the NW) an AI/ML model for the HARQ feedback generation function, for example if the WTRU supports AI/ML-based HARQ feedback reporting. At 502 the WTRU may receive (e.g., from the NW) a DL scheduling message and/or a configuration message. The DL scheduling message may include data allocation(s) of one or more transport blocks (TBs), an HARQ process ID of a (e.g., each) TB, a CBGTI and CBGFI for a (e.g., each) CBG (e.g., if data transmission is based on CBGs), an HARQ feedback report type (e.g., soft combining feedback message, decoding feedback message, CRC feedback message, and/or requested DL MCS, NDI, CBGTI, and/or CBGFI, etc.). The configuration message may include an HARQ feedback report format (e.g., explicit or a latent representation), MCS and/or UL precoder to be applied to the HARQ feedback report, and/or signals and/or the UL resource configuration/allocations that may carry the HARQ feedback report (e.g., PUSCH, PUCCH, RRC, UCI, and/or MAC-CE).

If the HARQ feedback report includes a latent representation for example, the configuration message may include a size of the latent representation (e.g., number of latent variables) and/or a configuration of the quantization operation to be applied to the latent representation. The configuration of the quantization operation to be applied to the latent representation may include the number of bits per latent variable, uniform/non-uniform quantization, and/or scalar/vector quantization, etc. The WTRU may receive the configuration message through one or more of DCI, MAC-CE, and/or RRC signaling.

At 504 the WTRU may receive a DL data. The WTRU may pass the received DL data through a receiver (e.g., channel estimation, equalization, and/or demodulation, etc.) and/or soft combining function. At 506 the WTRU may decode the received DL data and/or determine one or more decoding parameters.

The one or more decoding parameters may include a soft combining feedback message (e.g., from the soft combining function), a decoding feedback message, and/or a CRC feedback message. The soft combining feedback message (e.g., from the soft combining function) may be based on log-likelihood-ratios (LLRs) of the coded bits. The soft combining function may include a non-AI/ML function (e.g., legacy soft combining technique) and/or an AI/ML-based function (e.g., a neural network). If the soft combining function includes a non-AI/ML function for example, the soft combining feedback message may be explicit and/or may include statistics of the output LLRs, and/or resulting SINR after soft combining, etc.

If the soft combining function is an AI/ML-based function for example, the soft combining function may be designed either separately or jointly with the receiver functions (e.g., channel estimation, equalization, and/or demodulation, etc.). If the soft combining function is an AI/ML-based function that is designed jointly with the receiver functions for example, the WTRU may include a (e.g., single) AI/ML-based receiver and/or soft combining function. The AI/ML-based receiver and/or soft combining function may include the WTRU receiver functions (e.g., channel estimation, equalization, and/or demodulation, etc.) and/or the soft combining function. The WTRU may input the received DL data to the AI/ML-based function and/or output the LLRs of the coded bits transmitted by the NW. The WTRU may input previously generated LLRs to the AI/ML-based receiver and/or soft combining function. The soft combining feedback message may include a latent feedback message (e.g., a latent representation).

The decoding feedback message may include measured statistics of the decoding complexity, for example the number of iterations that the FEC decoder used to decode the resulting LLRs. The CRC feedback message may be explicit or a latent feedback message (e.g., a learnable feedback message). The CRC feedback message may include ACK/NACK bits and/or the total set of CRC bits.

At 508 the WTRU may determine the HARQ feedback report type, the HARQ feedback report format, and/or the HARQ feedback report, for example based on the received configuration message, the received DL data, the one or more determined decoding parameters, and/or the performance of the HARQ feedback generation function (e.g., AIML compression rate). The WTRU may input the decoding parameters to the HARQ feedback generation function and/or may generate an HARQ feedback report.

The HARQ feedback report may include an explicit feedback report or a latent feedback report (e.g., learnable and/or an output of an AI/ML model). The HARQ feedback generation function at the WTRU may include an AI/ML model, for example if the HARQ feedback report includes a latent feedback report. The WTRU may input the decoding parameters along and/or previously generated HARQ feedback reports to the AI/ML model and/or generates an HARQ feedback report, for example if the HARQ feedback report includes a latent feedback report. The WTRU may generate the HARQ feedback report in the form of a compressed/latent representation.

The WTRU may adjust the parameters of AI/ML-based HARQ feedback generation function (e.g., size of the latent representation), for example based on the decoding parameters. For example the NW may configure the WTRU with a (e.g., certain) feedback payload size. The WTRU may select a different size for the output latent representation and/or may select a subset of the decoding parameters to be reported to the NW, for example based on (e.g., as a function of) the decoding parameter(s). The WTRU may report its behavior to the NW. At 510 the WTRU may transmit the HARQ feedback report, for example using configured HARQ feedback report transmission parameters. Additionally, or alternatively, the WTRU may transmit the determined HARQ feedback report type and/or the HARQ feedback report format.

The NW may transmit an HARQ feedback capabilities request to the WTRU. The NW may receive the WTRU HARQ feedback capabilities from the WTRU, for example in response to the request. The NW may determine and/or transmit an (e.g., appropriate) AI/ML model for the HARQ feedback generation function to the WTRU, for example if the WTRU supports AI/ML-based HARQ feedback reporting. The NW may transmit a configuration message to the WTRU. The NW may transmit a DL data, for example carrying the DL data to the WTRU.

The NW may receive the HARQ feedback report type, the HARQ feedback report format, and/or the HARQ feedback report. The NW may input the extracted HARQ feedback report and/or available (e.g., received) CSI feedback reports (e.g., associated with prior DL channel sounding operations), for example to an HARQ processing function.

The NW may determine (e.g., reconstruct) the ACK/NACK feedback associated with the DL transmitted TBs and/or CBGs (e.g., if data retransmission is based on CBGs), and/or may generate a transmission and/or retransmission (Tx/ReTx) recommendation. The transmission and/or retransmission recommendation may include DL MCS, a predicted number of retransmissions for the generated MCS, a redundancy version, and/or a predicted number of retransmissions, etc.

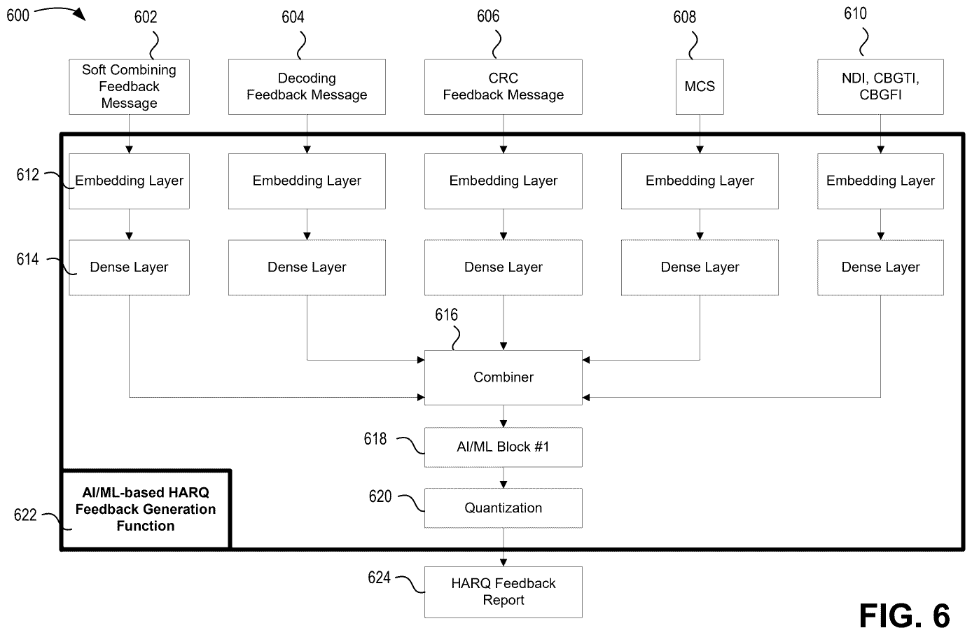

FIG. 6 is an example AI/ML model 600 of a HARQ generation function 622, for example an AI/ML-based HARQ generation function, at a WTRU. Input data to the AI/ML-based HARQ feedback generation function 622 may include a soft combining feedback message 602, a decoding feedback message 604, a CRC feedback message 606, a modulation and coding scheme (MCS) value 608, and one or more indicators such as a new data indicator (NDI), a code block group transmission indicator (CBGTI), and/or a code block group feedback indicator (CBGFI) 610. The soft combining feedback message 602 may be explicit, such as statistics of the output LLRs and/or resulting SINR after soft combining, and/or a latent representation, such as a vector and/or tensor of real and/or binary values, for example if a neural receiver and/or the soft combining function is an AI/ML-based function.

A (e.g., each) input data 602, 604, 606, 608, and 610 may be provided to a (e.g., corresponding) embedding layer 612, which may generate a representation such as a numerical representation or a real-valued representation of that input data. A (e.g., each) generated representation from the embedding layer 612 may (e.g., then) be provided to a (e.g., corresponding) dense layer 614. The generated representations may thereby be mapped into a shared space via learned transformations, such as mapping the generated representations to a common dimension. The outputs of the dense layers 614 may be combined by a combiner 616, such as via concatenation, addition, and/or another combination technique, for example to generate a single representation, such as a numerical representation or a real-valued representation.

The output of the combiner 616 may be provided to an AI/ML block 618. The AI/ML block 618 may include one or more hidden layers, such as one or more dense layers and/or one or more convolutional layers, to generate a latent representation. A quantization operation 620 may be applied to the latent representation generated by the AI/ML block 618 to generate a HARQ feedback report 624. The HARQ feedback report 624 may be output from the AI/ML-based HARQ feedback generation function 622.

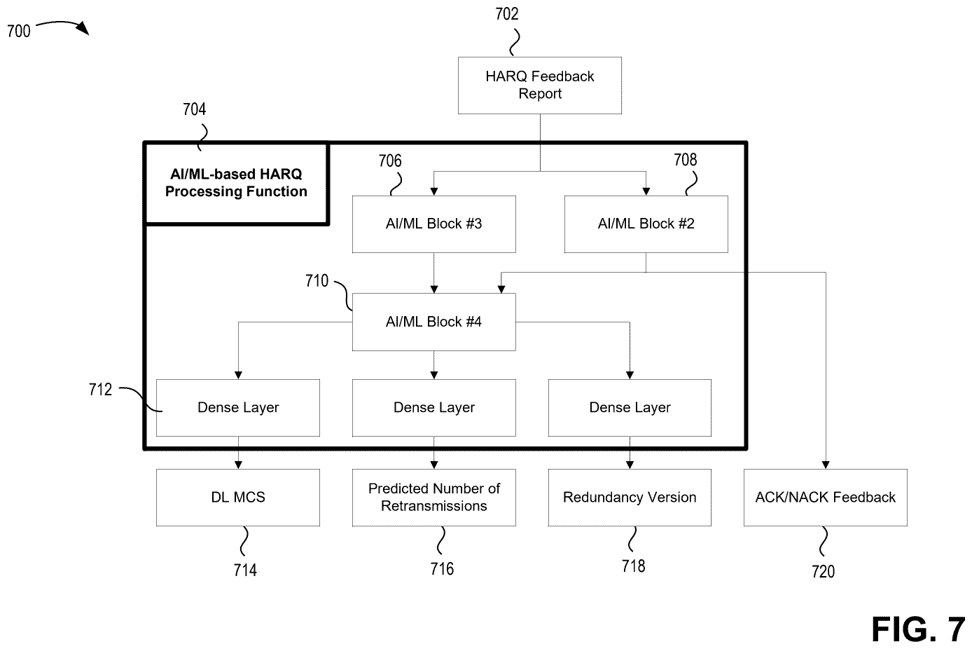

FIG. 7 is an example AI/ML model 700 of a HARQ generation function 704, for example an AI/ML-based HARQ generation function, at a network. The HARQ feedback report 702, for example received from the WTRU, may be input into AI/ML block #2 708 and AI/ML block #3 706 concurrently. Each of the AI/ML block #2 708 and AI/ML block #3 706 may include one or more hidden layers (e.g., dense layers, convolutional layers, and/or other types of neural layers). An ACK/NACK feedback 720 may be generated as an output of the AI/ML block #2 708. The output of the AI/ML block #3 706 and the ACK/NACK feedback 720 may (e.g., then) be input into an AI/ML block #4 710. The AI/ML block #4 710 may include one or multiple hidden layers (e.g., an addition layer, a concatenation layer, dense layers, convolutional layers, and/or other neural network layers). From the output of the AI/ML block #4 710, three different outputs may be concurrently generated. Each of the three outputs may be passed through a corresponding dense layer 712 to generate one of the components of a transmission/retransmission (Tx/ReTx) recommendation. The Tx/ReTx recommendation may include a downlink modulation and coding scheme (DL MCS) 714, a predicted number of retransmissions 716 for the generated DL MCS 714, and/or a redundancy version 718.

Output data may include the ACK/NACK feedback 720 associated with the DL transmitted transport blocks (TBs) and/or code block groups (CBGs) (e.g., when data transmission is based on CBGs), and/or the Tx/ReTx recommendation. The Tx/ReTx recommendation may include the DL MCS 714, the predicted number of retransmissions 716 for the generated DL MCS 714, and/or the redundancy version 718.

Based on the above, the AI/ML-based HARQ feedback may be a multi-task AI/ML-based function that may include two tasks. The first task (or a group of tasks) may include a ACK/NACK feedback reconstruction, and the second task (or a group of tasks) may include a Tx/ReTx recommendation. Training may be performed using curriculum learning to train the first and/or second tasks.

For the first task (e.g., the ACK/NACK feedback reconstruction) training may be performed online, for example jointly at the WTRU and the network. During training for example, the WTRU may transmit ground-truth ACK/NACK feedback to the network. The network may compute a loss function to be minimized. The loss function may be a measured distance (e.g., mean absolute error (MAE), binary cross entropy (BCE), and/or other distance functions) between the reconstructed ACK/NACK feedback generated by the AI/ML-based HARQ processing function 704 and the ground-truth ACK/NACK feedback received from the WTRU.

The network may compute derivatives of the loss function with respect to the received HARQ feedback report 702 from the WTRU in order to update the AI/ML model of the AI/ML-based HARQ processing function 704. The network may then transmit the computed derivatives to the WTRU. The WTRU may compute derivatives of the loss function with respect to the input data of the AI/ML-based HARQ feedback generation function and may update parameters of its AI/ML model accordingly. The network may continue to monitor training of the AI/ML-based HARQ feedback generation function and the AI/ML-based HARQ processing function 704 by evaluating the behavior of the loss function. If a value of the loss function falls below a certain threshold, the network may stop training and may notify the WTRU to stop the training.

After completing training of the first task, the WTRU may train the second task. For the second task, online end-to-end training may be performed, for example jointly at the WTRU and the network. During training, the WTRU may receive DL training data based on a Tx/ReTx recommendation designed by the network. The WTRU may compute a loss function to be minimized. The loss function to be minimized may be a measured distance, such as binary cross entropy (BCE), approximate bit error rate (BER), and/or approximate block error rate (BLER). The WTRU may compute derivatives of the loss function and/or may transmit the derivatives to the network. The network may (e.g., then) compute derivatives of the loss function with respect to the HARQ feedback report 702 received from the WTRU, for example to update the AI/ML model of the AI/ML-based HARQ processing function 704. The network may transmit the computed derivatives to the WTRU. The WTRU may compute derivatives of the loss function with respect to input data of the AI/ML-based HARQ feedback generation function and/or may update parameters of its AI/ML model (e.g., accordingly). The WTRU and/or the network may continue to monitor training of the AI/ML-based HARQ feedback generation function and/or the AI/ML-based HARQ processing function 704, or example by evaluating behavior of the loss function. If a value of the loss function is below a certain threshold for example, the WTRU and the network may stop training.

1. A wireless transmit/receive unit (WTRU) comprising:
a processor configured to:
receive configuration information from a network, the configuration information comprising an indication of a hybrid automatic request (HARQ) feedback report type and an indication of an HARQ feedback report format;
receive, from the network, a downlink scheduling message and a downlink transmission associated with the downlink scheduling message;
determine decoding parameters based on the downlink transmission, the decoding parameters comprising a soft combining feedback message, a decoding feedback message, and a cyclic redundancy check (CRC) feedback message;
generate a HARQ feedback report based on the decoding parameters and the downlink scheduling message, wherein the HARQ feedback report is associated with the HARQ feedback report type, the HARQ feedback report format; and
send the HARQ feedback report to the network.

2. The WTRU of claim 1, wherein the HARQ feedback report comprises an indication of at least one of a log-likelihood ratio (LLR) of coded bits associated with the soft combining feedback message, a decoding complexity associated with the downlink transmission, or cyclic redundancy check (CRC) bits associated with the CRC feedback message.

3. The WTRU of claim 1, wherein the HARQ feedback report format comprises an explicit indication or a latent representation for the HARQ feedback report.

4. The WTRU of claim 1, wherein the downlink scheduling message comprises at least one of a modulation and coding scheme (MCS), a data allocation associated with one or more transport blocks (TBs), a HARQ process identifier (ID) associated with the one or more TBs, code block group (CBG) transmission information (CBGTI), or CBG flushing out information (CBGFI) associated with the CBG.

5. The WTRU of claim 1, wherein the processor is configured to:
receive a request to transmit HARQ feedback capabilities to the network; and
transmit the HARQ feedback capabilities to the network, wherein the HARQ feedback capabilities comprise an indication of whether the WTRU supports artificial intelligence/machine learning (AI/ML)-based HARQ feedback.

6. The WTRU of claim 1, wherein the processor is configured to send the HARQ feedback report type and the HARQ feedback report format to the network with the HARQ feedback report.

7. The WTRU of claim 1, wherein the soft combining feedback message comprises an indication of at least one of a log likelihood ratios (LLR) or a signal to interference plus noise ratio (SINR), wherein the decoding feedback message comprises an indication of forward error correction (FEC), and wherein the CRC feedback message comprises an indication of at least one of a cyclic redundancy check (CRC), an acknowledgment (ACK), or a non-acknowledgment (NACK).

8. The WTRU of claim 1, wherein the processor is configured to determine the HARQ feedback report based on at least one artificial intelligence/machine learning (AI/ML) parameter, wherein the at least one AI/ML parameter is based on one or more of the decoding parameters.

9. The WTRU of claim 1, wherein the processor is configured to determine the HARQ feedback report based on an artificial intelligence/machine learning (AI/ML) compression rate.

10. The WTRU of claim 1, wherein the HARQ feedback report comprises at least one of an acknowledgment or a non-acknowledgement.

11. A method performed by a wireless transmit/receive unit (WTRU), the method comprising:
receiving configuration information from a network, the configuration information comprising an indication of a hybrid automatic request (HARQ) feedback report type and an indication of an HARQ feedback report format;
receiving, from the network, a downlink scheduling message and a downlink transmission associated with the downlink scheduling message;
determining decoding parameters based on the downlink transmission, the decoding parameters comprising a soft combining feedback message, a decoding feedback message, and a cyclic redundancy check (CRC) feedback message;
generating a HARQ feedback report based on the decoding parameters and the downlink scheduling message, wherein the HARQ feedback report is associated with the HARQ feedback report type, the HARQ feedback report format; and
sending the HARQ feedback report to the network.

12. The method of claim 11, wherein the HARQ feedback report comprises an indication of at least one of a log-likelihood ratio (LLR) of coded bits associated with the soft combining feedback message, a decoding complexity associated with the downlink transmission, or cyclic redundancy check (CRC) bits associated with the CRC feedback message.

13. The method of claim 11, wherein the HARQ feedback report format comprises an explicit indication or a latent representation for the HARQ feedback report.

14. The method of claim 11, wherein the downlink scheduling message comprises at least one of a modulation and coding scheme (MCS), a data allocation associated with one or more transport blocks (TBs), a HARQ process identifier (ID) associated with the one or more TBs, code block group (CBG) transmission information (CBGTI), or CBG flushing out information (CBGFI) associated with the CBG.

15. The method of claim 11, comprising:
receiving a request to transmit HARQ feedback capabilities to the network; and
transmitting the HARQ feedback capabilities to the network, wherein the HARQ feedback capabilities comprise an indication of whether the WTRU supports artificial intelligence/machine learning (AI/ML)-based HARQ feedback.

16. The method of claim 11, comprising sending the HARQ feedback report type and the HARQ feedback report format to the network with the HARQ feedback report.

17. The method of claim 11, wherein the soft combining feedback message comprises an indication of at least one of a log likelihood ratios (LLR) or a signal to interference plus noise ratio (SINR), wherein the decoding feedback message comprises an indication of forward error correction (FEC), and wherein the CRC feedback message comprises an indication of at least one of a cyclic redundancy check (CRC), an acknowledgment (ACK), or a non-acknowledgment (NACK).

18. The method of claim 11, comprising determining the HARQ feedback report based on at least one artificial intelligence/machine learning (AI/ML) parameter, wherein the at least one AI/ML parameter is based on one or more of the decoding parameters.

19. The method of claim 11, comprising determining the HARQ feedback report based on an artificial intelligence/machine learning (AI/ML) compression rate.

20. The method of claim 11, wherein the HARQ feedback report comprises at least one of an acknowledgment or a non-acknowledgement.
